(19) United States
(12) Patent Application Publication
(10) Pub. No.: US 2011/0017604 A1
(43) Pub. Date: Jan. 27, 2011

(54) Method for making semiconductor electrodes

(75) Inventors: Wu Chih-Hung, Taoyuan County (TW); Chao Chih-Kang, Taoyuan County (TW); Kao Chi-Joe, Taoyuan County (TW); Lu Zih-Sian, Taoyuan County (TW); Liu Keng-Shen, Taoyuan County (TW); Chen Ying-Ru, Taoyuan County (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 12/081,948

(22) Filed: Apr. 23, 2008

(51) Int. Cl. H01L 21/445

(52) U.S. Cl. 205/123

(57) ABSTRACT

Disclosed is a method for making semiconductor electrodes. In the method, there is provided a wafer. The wafer includes first metal layers. A second metal layer is provided on the wafer so that the first metal layers are shielded with the second metal layer. Photo-resist is provided on the second metal layer so that the first metal layers are not shielded with the photo-resist. An electroplating device is used to provide third metal layers on the second metal layer so that each of the first metal layers is shielded with a related one of the third metal layers. The wafer is divided from the photo-resist, thus forming semiconductor electrodes.

### FIELD OF THE INVENTION

The present invention relates to a method for making semiconductor electrodes and, more particularly, to a simple and compatible method for making semiconductor electrodes without a high carrier concentration, with a high throughput, at a low cost.

### DESCRIPTION OF THE RELATED ART

Referring to FIG. 10, a plurality of electrode layers 61 is provided on a conventional semiconductor device 6. Photo-resist 62 is provided on portions of the semiconductor device 6 that are not covered with the electrode layers 61. Several metal layers 63 are provided on each of the electrode layers 61 via electroplating. A portion of the semiconductor device 6, the related the electrode layer 61 and the related metal layers 63 together form a semiconductor electrode.

Because of the current crowding effect, it is difficult to obtain uniform thickness of the metal layers 63. The semiconductor device 6 must be made with a high carrier concentration so that it exhibits good conductivity that results in uniform current distribution that causes uniform thickness of the metal layers 63. Therefore, the cost is high, the throughput is low and the process is complicated.

The present invention is therefore intended to obviate or at least alleviate the problems encountered in prior art.

### SUMMARY OF THE INVENTION

It is the primary objective of the present invention to provide a simple and compatible method for making semiconductor electrodes without a high carrier concentration, with a high throughput, at a low cost.

To achieve the foregoing objective, the method includes the step of providing a wafer with first metal layers. A second metal layer is provided on the wafer so that the first metal layers are shielded with the second metal layer. Photo-resist is provided on the second metal layer so that the first metal layers are not shielded with the photo-resist. An electroplating device is used to provide third metal layers on the second metal layer so that each of the first metal layers is shielded with a related one of the third metal layers. The wafer is divided from the photo-resist, thus forming semiconductor electrodes.

Other objectives, advantages and features of the present invention will become apparent from the following description referring to the attached drawings.

### BRIEF DESCRIPTION OF THE DRAWINGS

The present invention will be described via the detailed illustration of the preferred embodiment referring to the drawings.

FIG. 1 is a top view of a wafer for use in a method for making semiconductor electrodes according to the preferred embodiment of the present invention;

FIG. 2 is a top view of a second metal layer provided on first metal layers of the wafer shown in FIG. 1.

FIG. 3 is a cross-sectional view of the wafer shown in FIG. 2.

FIG. 4 is a cross-sectional view of photo-resist provided on the wafer shown in FIG. 3.

FIG. 5 is a top view of an electroplating device and the wafer shown in FIG. 4.

FIG. 6 is a cross-sectional view of third metal layers provided on the second metal layer of the wafer shown in FIG. 4.

FIG. 7 is a cross-sectional view for showing a step for etching the wafer shown in FIG. 6.

FIG. 8 is a cross-sectional view for showing a step for cutting the wafer shown in FIG. 6.

FIG. 9 is a cross-sectional view of a semiconductor electrode made in the etching step shown in FIG. 7 or the cutting step shown in FIG. 8.

FIG. 10 is a top view of another electroplating device for use in the method according to the present invention.

FIG. 11 is a cross-sectional view of conventional semiconductor electrodes.

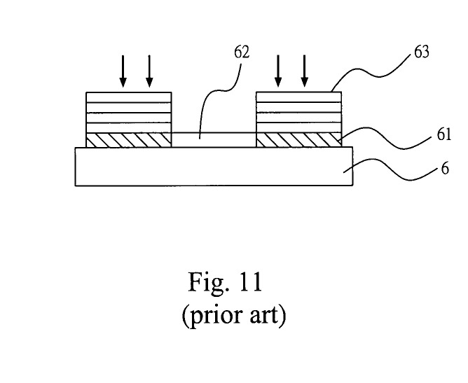

### DESCRIPTION OF THE PREFERRED EMBODIMENT

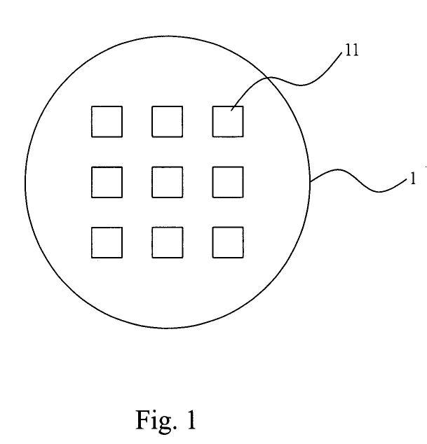

Referring to FIG. 1, there is provided a wafer 1 for use in a method for making semiconductor electrodes according to the preferred embodiment of the present invention. The wafer 1 includes a plurality of first metal layers 11 separated from one another. The first metal layers 11 may be made of gold-germanium alloy, gold-zinc alloy, gold-beryllium alloy, titanium, platinum or gold.

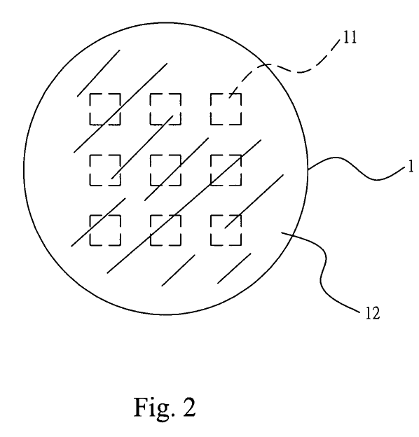

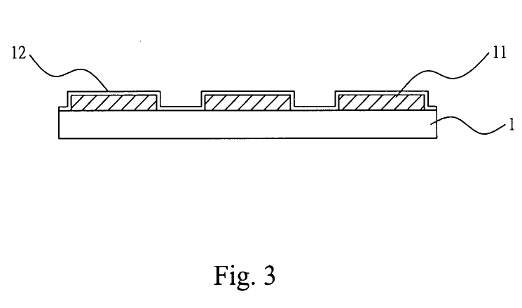

Referring to FIGS. 2 and 3, a second metal layer 12 is provided on the wafer 1 so that the first metal layers 11 are covered by the second metal layer 12. The second metal layer 12 is made of gold, silver or titanium. The thickness of the second metal layer 12 is 100 to 10000 angstroms.

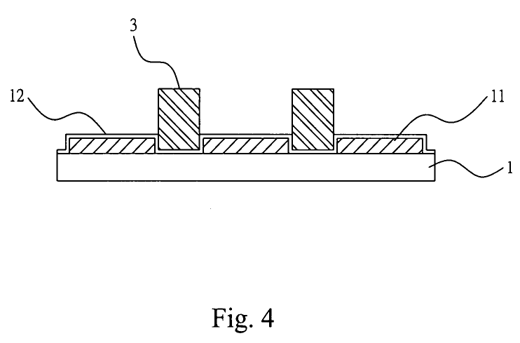

Referring to FIG. 4, photo-resist 3 is provided on the second metal layer so that the first metal layers 11 are not shielded with the photo-resist 3.

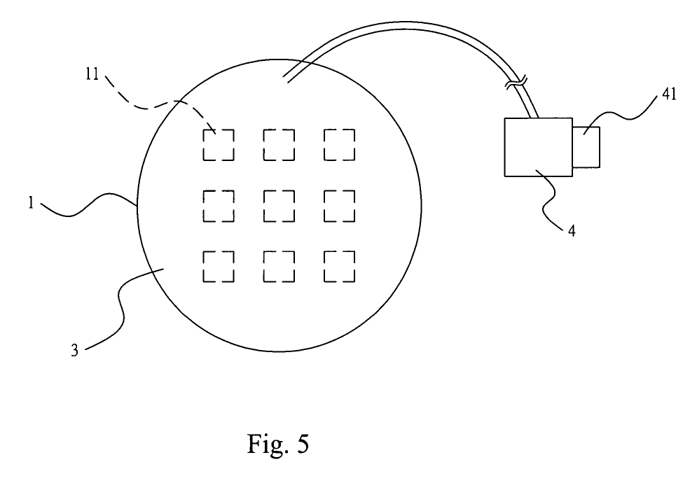

Referring to FIG. 5, an electroplating device 4 is connected to the second metal layer 12. Target material 41 is used in the electroplating device 4. The target material 41 is gold, silver or gold-silver alloy. An electrode 46 of the electroplating device 4 is connected to the second metal layer 12 with a wire or probe.

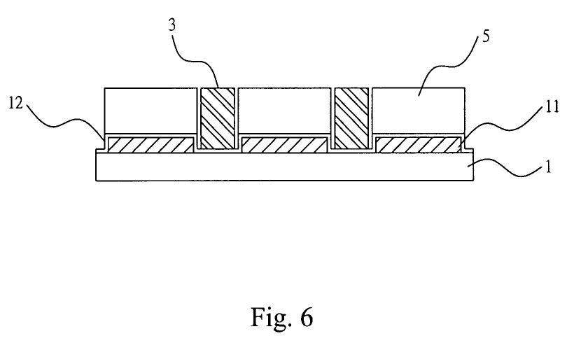

Referring to FIG. 6, third metal layers 5 are provided on the second metal layer 12 so that each of the first metal layers 1 is shielded with a related one of the third metal layers 5. The third metal layers 5 are made of gold, silver or gold-silver alloy corresponding to the target material 41.

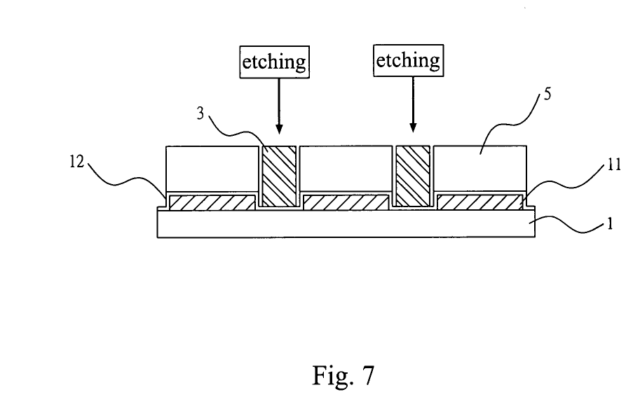

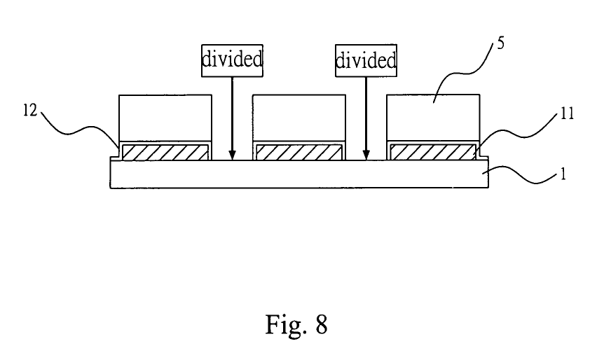

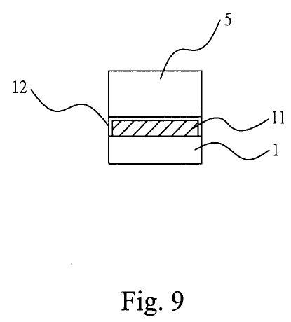

Then, the wafer 1 is divided into semiconductor electrodes. One of the semiconductor electrodes is shown in FIG. 9. The dividing may be done in an etching step as shown in FIG. 7 or a cutting step as shown in FIG. 8. Referring to FIG. 7, the wafer 1 is etched from the photo-resist 3. Referring to FIG. 8, the wafer 1 is cut from the photo-resist 3.

The second metal layer 12 is used to ensure uniform current distribution so that the third metal layers 13 are made with even thickness. Therefore, there is no need to make the wafer 1 with a high carrier concentration.

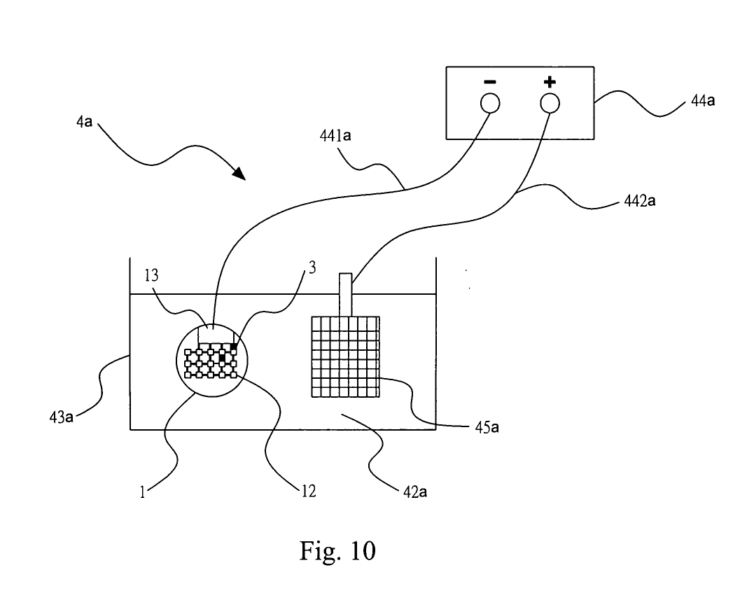

Referring to FIG. 10, an electroplating device 4a can be used instead of the electroplating device 4. The electroplating device 4a includes a container 43a and a power supply 44a. The container 43a is used to contain electrolyte 42a. The electrolyte 42a includes gold, silver or gold-silver alloy. The power supply 44a includes an electrode 441a connected to the second metal layer and an electrode 442a connected to a mesh 45a. The mesh 45a is made of platinum or titanium alloy. The wafer 1 and the mesh 45a are submerged in the electrolyte 42a.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A method for making semiconductor electrodes comprising the steps of:
providing a wafer with first metal layers;
providing a second metal layer on the wafer so that the first metal layers are shielded with the second metal layer;
providing photo-resist on the second metal layer so that the first metal layers are not shielded with the photo-resist;
using an electroplating device to provide third metal layers on the second metal layer so that each of the first metal layers is shielded with a related one of the third metal layers; and
dividing the wafer from the photo-resist, thus forming semiconductor electrodes.

2. The method according to claim 1, wherein the first metal layers are made of a material selected from a group consisting of gold-germanium alloy, gold-zinc alloy, gold-beryllium alloy, titanium, platinum and gold.

3. The method according to claim 1, wherein the second metal layer is made of at least one material selected from a group consisting of gold, silver and titanium.

4. The method according to claim 1, wherein the thickness of the second metal layer is 100 to 10000 angstroms.

5. The method according to claim 1, wherein the electroplating device comprises target material and an electrode connected to the second metal layer.

6. The method according to claim 5, wherein the electroplating device comprises a wire for connecting the electrode to the second metal layer.

7. The method according to claim 5, wherein the electroplating device comprises a probe for connecting the electrode to the second metal layer.

8. The method according to claim 5, wherein the target material comprises at least one material selected from a group consisting of gold and silver.

9. The method according to claim 1, wherein the third metal layer is made of at least one material selected from a group consisting of gold and silver.

10. The method according to claim 1 comprising an etching step for dividing the wafer into the semiconductor electrodes.

11. The method according to claim 1 comprising a cutting step for dividing the wafer into the semiconductor electrodes.

12. The method according to claim 1, wherein the electroplating device comprises:
a container for containing electrolyte; and
a power supply comprising a first electrode connected to the second metal layer and a second electrode connected to a mesh made of a material selected from a group consisting of platinum and titanium alloy.

13. The method according to claim 12, wherein the electroplating device comprises a wire for connecting the first electrode to the second metal layer.

14. The method according to claim 12, wherein the electroplating device comprises a probe for connecting the first electrode to the second metal layer.

15. The method according to claim 12, wherein the electrolyte comprises at least one material selected from a group consisting of gold and silver.
